(19) United States
(12) Patent Application Publication
(10) Pub. No.: US 2007/0181531 A1
(43) Pub. Date: Aug. 9, 2007

(54) PLASMA PROCESSING APPARATUS AND PLASMA PROCESSING METHOD

(75) Inventors: Takahiro Horiguchi, Tsukui-gun (JP); Tadahiro Ohmi, Sendai-shi (JP); Masaki Hirayama, Sendai-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Tokyo (JP); NATIONAL UNIVERSITY CORPORATION TOHOKU UNIVERSITY, Sendai-shi (JP)

(21) Appl. No.: 11/671,787

(22) Filed: Feb. 6, 2007

(30) Foreign Application Priority Data
Feb. 6, 2006 (JP) 2006-028849

(51) Int. Cl. C23F 1/00; H01L 21/306; H01L 21/302; H01L 21/461; B44C 1/22

(52) U.S. Cl. 216/67; 438/710; 156/345.1; 156/345.36; 156/345.33

(57) ABSTRACT

A microwave plasma processing apparatus 100 includes a plurality of dielectric parts 31, through which microwaves are transmitted via a slot, and gas nozzles 27 disposed at positions lower than the dielectric parts 31. The dielectric parts 31 and the gas nozzles 27 are each constituted with a porous portion and a dense portion. A first gas supply unit supplies argon gas into a processing chamber through porous portions 31P at the individual dielectric parts 31. A second gas supply unit supplies silane gas and hydrogen gas into the processing chamber through porous portions 27P at the gas nozzles 27. The gases decelerate as they travel through the porous portions and, as a result, excessive agitation in the gases can be inhibited. Consequently, uniform plasma is generated and a high quality amorphous silicon film can be formed with the plasma.

### CROSS REFERENCE TO RELATED APPLICATIONS

The present invention contains subject matter related to Japanese Patent Application No. JP 2006-28849, filed at the Japan Patent Office Feb. 6, 2006, the entire contents of which are incorporated herein by reference.

### BACKGROUND OF THE INVENTION

1. Field of the Invention

The present invention relates to a plasma processing apparatus and a plasma processing method to be adopted when executing plasma processing on a workpiece by generating plasma. In particular, the present invention relates to how a gas to be used in plasma generation may be supplied.

2. Description of the Related Art

A gas being injected into a plasma processing chamber needs to be delivered evenly into the entire processing chamber without allowing it to flow in a substantially greater quantity in any particular direction while sustaining the pressure around the gas injection holes at a uniform level by lowering to a sufficient extent the flow velocity of the gas being injected into the processing chamber, so as to inhibit excessive agitation in the gas within the plasma processing chamber. The gas flow velocity can be lowered and then the gas can be injected evenly into the entire processing chamber through gas injection holes with a large opening. However, such large gas injection holes give rise to an issue in that the gas injected through gas injection holes further away from a gas supply source flows in smaller quantities, resulting in ununiformity in plasma density.

Accordingly, gas supply methods wherein a porous material is disposed over the gas supply area have been proposed in the related art (for instance, see Japanese Laid Open Patent Publication No. 2001-220678). In a plasma processing apparatus adopting such a method, a high frequency electrode (cathode) is disposed at a position facing opposite a ground electrode (anode) and the cathode is constituted with a cathode main body and a porous portion. In the apparatus, the gas, having been taken into the space between the cathode main body and the porous portion, then passes through the pores in the porous portion and thus is injected through the cathode surface, into the processing chamber while lowering its flow velocity to a sufficient extent.

### SUMMARY OF THE INVENTION

However, it has not been feasible so far to directly adopt this method in a microwave plasma processing apparatus in which the gas is injected into the processing chamber through the openings of a plurality of gas supply pipes, since the presence of the porous material at the openings of the gas supply pipes would not allow the internal spaces of the gas supply pipes where the pressure is kept at 1 atmosphere and the internal space in the processing chamber where the pressure is sustained at the vacuum pressure level, cannot be isolated from each other completely, which would make it impossible to assure the required level of airtightness for the processing chamber. For this reason, no effective method for lowering the flow velocity of the gas injected into the processing chamber in a microwave plasma processing apparatus has been proposed to date.

Accordingly, the present invention addresses the problems of the related art discussed above by providing a new and improved plasma processing apparatus and a new and improved plasma processing method with which the gas flow velocity is effectively lowered and thus desirable plasma processing is enabled.

Namely, according to an embodiment of the present invention, there is provided a plasma processing apparatus in which plasma is generated with a predetermined gas excited by a microwave and a subject to be processed is processed by the generated plasma, the plasma processing apparatus including a processing chamber in which the subject to be processed is processed with plasma, a gas supply unit that supplies the predetermined gas into the processing chamber,

and a microwave supply unit that supplies the microwave into the processing chamber via slots provided in an antenna and via a dielectric member through which the microwave is transmitted. The dielectric member has at least partially a porous member and the predetermined gas is introduced into the processing chamber through the porous member.

The porous portion (the porous member) through which the gas passes is formed by mixing ceramic crystals, glass (e.g., SiO2) and distilled water. Namely, the porous portion assumes an internal structure achieved by bonding the ceramic crystals retaining their initial shapes via the glass. The average diameter of the pores in the porous portion may be approximately 10˜150 μm and the porosity of the porous portion may be approximately 20˜40% with the pores between the ceramic crystals in communication with one another.

The gas flow velocity Vt is normally expressed as an (1) below:
Vt=Q/A (1)

Assuming that the pressure P inside the processing container is 1 (Torr), that the total flow rate Q of the gas injected into the processing container is 3.33×10⁻⁵ (1/m³) and that the pressure P and the volume v in the processing container are constant, the flow velocity Vt of the gas injected through the porous portion can be calculated as expressed below. It is to be noted that the total sectional area A is calculated as the product of the total area of the dielectric member and the porosity, and that the total area of the dielectric member is 0.243 (m²) and the porosity is 35% in this example. In addition, it is assumed that 1(atm)=760 (Torr).
Vt=(3.33×10⁻⁵×760)/(0.243×35%)=0.3 m/s

In addition, assuming that the diameter of injection holes at a gas showerhead used in the related art is 0.5 mm, that there are 312 injection holes formed at the gas showerhead, that the pressure P inside the processing container is 1 (Torr), that the gas is injected into the processing container at a total flow rate Q of 3.33×10⁻⁵ (1/m³) and that the pressure P inside the processing container and the volumetric capacity v of the processing container remain constant, the flow velocity V0 of the gas injected through the injection holes at the gas showerhead in the related art is calculated as indicated below. It is to be noted that the total sectional area A is calculated as the product (6.13×10⁻⁵×312) of the injection hole sectional area and the number of injection holes.
V0=3.33×10⁻⁵×760)/(613×10⁻⁵×312)=380 m/s

These calculation results indicate that the flow velocity V0 of the gas injected through the injection holes in the related art is close to the speed of sound. This means that plasma processing cannot be executed in a desirable manner when two gas supply mechanism systems are utilized to inject a gas, to be used to excite plasma, and a gas, to be used to process the workpiece (a subject to be processed), e.g., to oxidize, nitrogen-fix, etch or CVD-process the workpiece, at different positions, since the different gases become agitated and mix with each other to an excessive extent in the processing chamber. In contrast, the flow velocity Vt of the gas injected through the porous portion according to the present invention is very low, i.e., approximately 1/1000 of the speed of sound. Thus, the individual gases do not become excessively agitated and are delivered at the desired positions.

Furthermore, according to the present invention, the gas traveling through numerous flow passages inside the porous portion decelerates and becomes evenly dispersed over the entire porous portion. It is then evenly injected into the processing chamber at an extremely low speed through the entire lower surface of the porous portion without flowing in a significantly greater quantity in any particular direction. Thus, desirable plasma can be evenly generated from various gas constituents delivered evenly at a specific position in a decelerated state and the workpiece can then be processed with the plasma in an optimal manner.

The dielectric member may include the porous member and a dense member. The porous member and the dense member may be formed to constitute the dielectric member by being integrally sintered. The dense member of the dielectric member may be disposed at a specific position so as to assure sealing of the processing chamber. In this case, uniform plasma can be generated by evenly supplying the gas, having become decelerated while passing through the porous portion, into the processing chamber with the dense portion (the dense member) assuring a desired level of seal in the processing chamber. It is to be noted that the specific position at which the dense portion is disposed is the position at which the internal space in a gas supply pipe or a slot opening, where the pressure is sustained at 1 atmosphere, is isolated from the internal space in the processing chamber, where the pressure is sustained at the vacuum pressure level.

The dielectric member may be constituted with a plurality of dielectric parts through which the microwave supplied via a single slot or a plurality of slots is transmitted, and each of the plurality of the dielectric parts may include a porous member and a dense member, and the gas supply unit may include a first gas supply unit that supplies a first gas of the predetermined gas into the processing chamber through the porous member formed at the each of the plurality of the dielectric parts.

At least any one of a recessed portion and a projecting portion may be formed at the surface of the each of the plurality of the dielectric parts, which surface faces the subject to be processed. At least any one of a recessed portion and a projecting portion may be formed at the surface of the porous member of the each of the plurality of the dielectric parts, which surface faces the subject to be processed. The presence of the recessed portion or the projecting portion at each dielectric part increases the extent of the electrical field energy loss occurring as a surface wave is propagated at the surface of the dielectric part. Thus, uniform plasma can be generated by inhibiting propagation of the surface wave and thus inhibiting the occurrence of a standing wave.

The plasma processing apparatus may further include a plurality of gas injection members are comprised of a porous member and a dense member, and the gas supply unit may include a second gas supply unit that supplies a second gas of the predetermined gas into the processing chamber through the porous member formed at each of the plurality of the gas injection members at a position lower than a position at which the first gas is introduced.

The gas injection members may be fixed onto beam supporting the dielectric parts. In addition, the plurality of dielectric parts may be supported by a latticed beam, and the beam may be constituted of nonmagnetic material. The gas injection members may include a dense member disposed on the exterior thereof and the porous member formed within the dense member so as to supply the second gas into the processing chamber through the porous member formed at the each of the plurality of the gas injection members at the position lower than the position at which the first gas is introduced.

In the plasma processing apparatus, the first gas (e.g. a plasma excitation gas such as an argon gas) is supplied through the porous portions at the dielectric member and the second gas (e.g. a processing gas such as a silane gas) is supplied through the porous portions at the gas injection members. The structure allows the first gas to be injected into the upper space in the processing chamber as its flow decelerates and the second gas to be injected into the lower space (a position lower than the first gas injection position) in the processing chamber as its flow decelerates. As a result, the first gas and the second gas do not become agitated and thus, generation of inconsistent plasma is inhibited.

Furthermore, the porous member and the dense member including the each of the plurality of the dielectric parts may be formed together by being integrally sintered, and the porous member and the dense member including the each of the plurality of the gas injection members may be formed together by being integrally sintered. Since the porous portion and the dense portion, having been baked together (be formed together by being integrally sintered), are bonded without any gap in between, a dielectric member with better performance against thermal expansion compared to a dielectric member in the related art achieved by manufacturing the porous portion and the dense portion separately from each other and binding them together with an adhesive can be provided. As a result, the gas passed through the porous portion and become decelerated in the process can be delivered into the processing chamber while assuring the desired level of airtightness in the processing chamber U with the dense portions isolating the internal space in a gas supply pipe or a slot opening where the pressure is sustained at 1 atmosphere from the internal space in the processing chamber where the pressure is sustained at the vacuum pressure level.

In addition, since the porous portion and the dense portion are not manufactured separately but are manufactured together through integrated baking, it is not necessary to perform, for instance, a process of aligning the bonding surfaces of the porous portion and the dense portion, which, in turn, allows the manufacturing costs to be greatly reduced. Moreover, the dielectric parts, achieving a high level of thermal expansion withstanding performance, are not readily damaged during plasma processing. As a result, the plasma processing apparatus can be engaged in operation in a stable manner.

The dielectric parts and the gas injection members may be each sealed through a sol-gel method. After coating (sealing) the porous portions with Y2O3 sol with a high level of corrosion resistance by soaking the porous portions of the dielectric member and gas injection members in the Y2O3 sol, the porous portions may be gelled through a heat treatment so as to inhibit the glass material (SiO2) in the porous portions from becoming corroded by an F gas or a chlorine gas.

At least any one of the first gas and the second gas may be a mixed gas containing a plurality of gas constituents and the binding energy of the first gas may be greater than the binding energy of the second gas unless the mixed gas induces an excessive reaction.

When the first gas and the second gas satisfy the conditions described above, the first gas with the higher level of binding energy is raised to plasma with the electrical field energy of the intense microwaves having just entered the processing chamber. Following plasma ignition of the first gas, the second gas with a lower level of binding energy compared to the first gas is injected at a position lower than the first gas injection position. The first gas and the second gas, both decelerating, are injected at different positions from each other, and thus, the first and second gases do not become agitated and mix with each other to an excessive extent. As a result, the second gas becomes dissociated until it achieves a precursor state in which a good-quality film can be formed with the microwave electrical field energy having become weaker after using up the power in order to raise the first gas to plasma (the dissociation does not progress beyond the precursor state). This means that the workpiece can be plasma-processed with a high level of accuracy.

It is to be noted that under a special set of circumstances, e.g., when either at least the first gas or the second gas is a mixed gas containing a plurality of types of gas constituents and this mixed gas induces an excessive reaction, the gas injection positions at which the first gas and the second gas are injected should be determined by ensuring that no excessive reaction occurs, regardless of the binding energy levels of the first gas and the second gas.

According to another embodiment of the present invention, there is provided a plasma processing method for generating plasma with a predetermined gas excited by a microwave and processing a subject to be processed by the generated plasma, the plasma processing method including steps of, supplying the microwave into a processing chamber via a dielectric member through which the microwave is transmitted, introducing the gas into the processing chamber through a porous member that the dielectric member has at least partially, and generating plasma with the introduced gas excited by the microwave supplied into the processing chamber.

The gas is supplied into the processing chamber after having passed through the porous portion. As a result, the gas flow velocity is lowered to approximately 1/1000 of the speed of sound and the decelerated gas penetrates the porous portion through the bottom thereof while becoming evenly distributed through the porous portion. The gas is then evenly injected into the processing chamber through the entire porous portion. As a result, plasma can be generated in a desirable manner without creating excessive agitation in the gas being supplied.

The dielectric member may include the porous member and a dense member formed together by being integrally sintered, and may include step of introducing the gas into the processing chamber through a porous member while assuring sealing of the processing chamber with the dense member.

In addition, the plasma processing method may include steps of transmitting the microwave through a plurality of dielectric parts constituting the dialectic member via a single slot or a plurality of slots, and introducing a first gas of the predetermined gas into the processing chamber through the porous member that each of the plurality of the dielectric parts has at least partially.

Furthermore, a plurality of gas injection members may include a porous member and a dense member integrally sintered; and the plasma processing method may include step of introducing a second gas of the predetermined gas into the processing chamber through the porous member formed at each of the plurality of the gas injection members at a position lower than a position at which the first gas is introduced while assuring sealing of the processing chamber with the dense member.

Since the porous portion and the dense portion, having been baked together, are bonded without any gap in between, a dielectric member with better performance against thermal expansion compared to a dielectric member in the related art achieved by manufacturing the porous portion and the dense portion separately from each other and binding them together with an adhesive can be provided. As a result, the gas having passed through the porous portion and having become decelerated in the process can be delivered into the processing chamber while assuring the desired level of airtightness in the processing chamber U with the dense portion isolating the internal space in a gas supply pipe or a slot opening where the pressure is sustained at 1 atmosphere from the internal space in the processing chamber where the pressure is sustained at the vacuum pressure level.

Furthermore, at least any one of the first gas and the second gas may be a mixed gas containing a plurality of gas constituents, and the plasma processing method may include step of introducing the first gas of which binding energy is greater than the binding energy of the second gas into the processing chamber through the porous member formed at each of a plurality of dielectric parts constituting the dialectic member and introducing the second gas of which binding energy is lower than the binding energy of the first gas into the processing chamber through the porous member formed at the each of the plurality of the gas injection members unless the mixed gas induces an excessive reaction.

Furthermore, at least either the first gas or the second gas may be a mixed gas containing a plurality of different gases, and unless the mixed gas induces an excessive reaction, the first gas with a higher level of binding energy than the second gas may be supplied into the upper space in the processing chamber through the porous portions in the dielectric member and the second gas with the lower level of binding energy than the first gas may be supplied into the lower space in the processing chamber through the porous portions in the gas injection members.

In this case, except for when the mixed gas induces an excessive reaction, the first gas with the higher binding energy is supplied into the upper space in the processing chamber through the porous portions in the dielectric parts and the second gas with lower binding energy is supplied into the lower space in the processing chamber through the porous portions in the gas injection member. As a result, since the first gas and the second gas, gradually decelerating, are injected at positions different from each other, excessive agitation in the gases is inhibited to ensure that desirable plasma is generated uniformly.

As explained above, the present invention provides a new and improved plasma processing apparatus and a new and improved plasma processing method, with which desirable plasma processing is enabled by reducing the gas flow velocity.

### BRIEF DESCRIPTION OF THE DRAWINGS

FIG. 1 is a sectional view of the microwave plasma processing apparatus achieved in a first embodiment of the present invention;

FIG. 2 is a view of the ceiling of the processing container achieved in the embodiment;

FIG. 3 is an enlargement of an area near the dielectric parts and the gas nozzles in FIG. 1;

FIG. 4 shows a positional arrangement that may be adopted in conjunction with the porous portions and the dense portions in each dielectric part and the internal structures of the porous portions and the dense portions;

FIG. 5 presents another example of positional arrangement that may be adopted in conjunction with the porous portions and the dense portions in the dielectric parts; and

FIG. 6 presents yet another example of positional arrangement that may be adopted in conjunction with the porous portions and the dense portions in the dielectric parts.

### DETAILED DESCRIPTION OF THE EMBODIMENT

Hereinafter, preferred embodiments of the present invention will be described in detail with reference to the appended drawings. Note that, in this specification and the appended drawings, structural elements that have substantially the same function and structure are denoted with the same references, and repeated explanation of these structural elements is omitted.

In addition, the description in the specification is provided by assuming that 1 mTorr is substantially equal to (10⁻³×101325/760) Pa and that 1 sccm is substantially equal to (10^{-6′}/60) m³/sec.

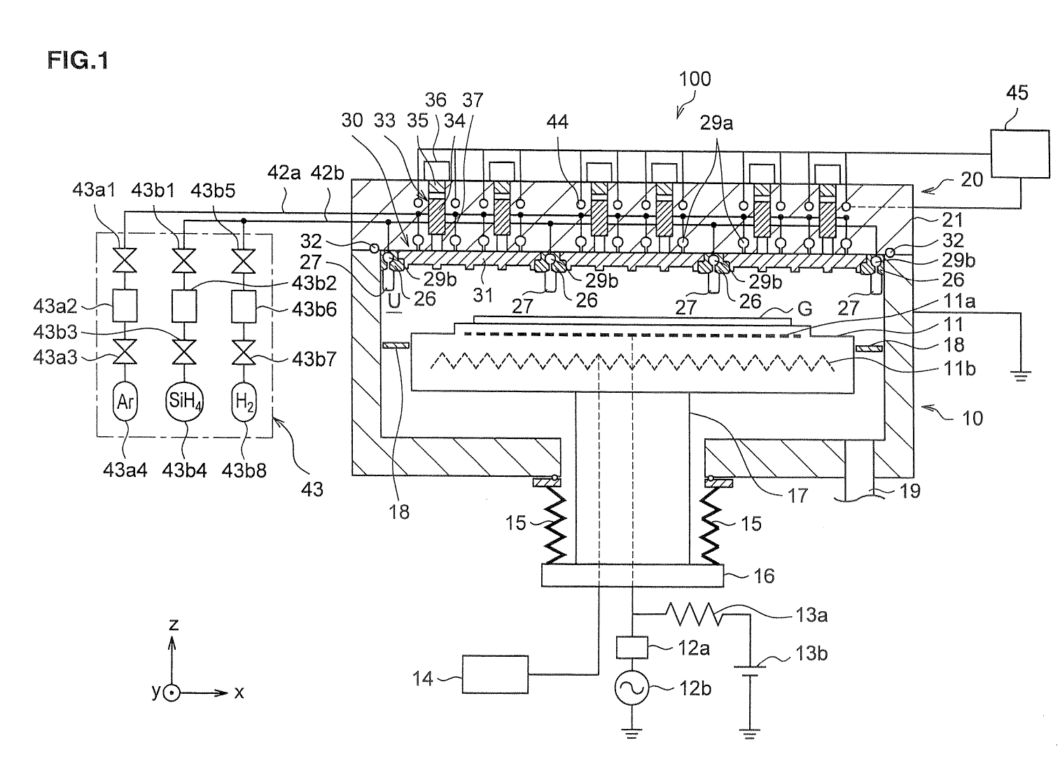

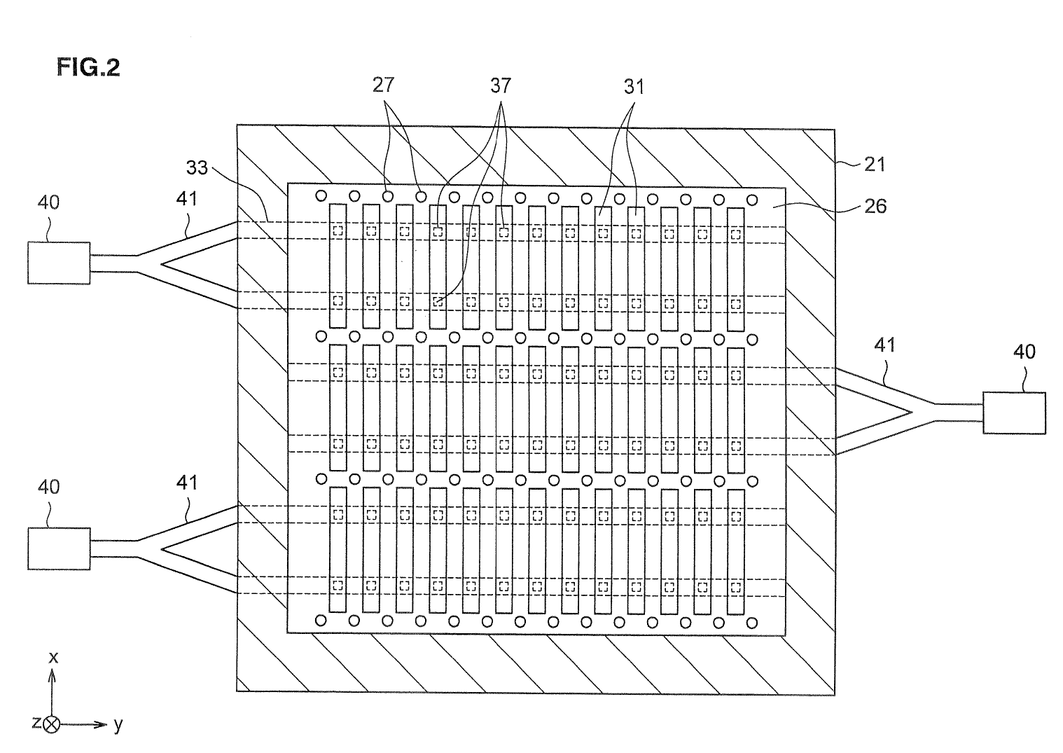

First, in reference to FIG. 1 presenting a sectional view of the microwave plasma processing apparatus achieved in an embodiment of the present invention, taken along the longitudinal direction (the direction perpendicular to the y-axis) and FIG. 2 presenting a view of the ceiling of the processing chamber, the structure adopted in the microwave processing apparatus is explained. It is to be noted that the following explanation focuses on an amorphous silicon CVD (Chemical Vapor Deposition) process executed in the microwave plasma processing apparatus (one example for the “plasma processing apparatus”) achieved in the embodiment.

(Structure Adopted in the Microwave Plasma Processing Apparatus)

A microwave plasma processing apparatus 100 includes a processing container 10 and a lid 20. The processing container 10 assumes a rectangular parallelepiped shape with an open top and a solid-bottom. The processing container 10 and the lid 20 are sealed together via an O-ring 32 disposed between the external circumference of the bottom surface of the lid main body 21 and the external circumference of the top surface of the processing container 10, thereby the processing container 10 and the lid 20 are secured so as to keep airtightness in the processing chamber, forming a processing chamber U where plasma processing is executed. The processing container 10 and the lid 20, which may be constituted of a metal such as aluminum, are electrically grounded.

Inside the processing container 10, a susceptor 11 (stage) on which a glass substrate (hereinafter referred to as a “substrate”) G is placed is disposed. Inside the susceptor 11 constituted of, for instance, aluminum nitride, a power supply unit 11a and a heater 11b are installed.

A high-frequency power source 12b is connected to the power supply unit 11a via a matcher 12a (e.g., a capacitor). In addition, a high-voltage DC power source 13b is connected to the power supply unit 11a via a coil 13a. The matcher 12a, the high-frequency power source 12b, the coil 13a and the high-voltage DC power source 13b are all disposed outside the processing container 10. The high-frequency power source 12b and the high-voltage DC power source 13b are grounded.

The power supply unit 11a applies a predetermined level of bias voltage into the processing container 10 by using high-frequency power output from the high-frequency power source 12b. In addition, the power supply unit 11a electrostatically adsorbs the substrate G with a DC voltage output from the high-voltage DC power source 13b.

An AC power source 14 disposed outside the processing container 10 is connected to the heater 11b, and the heater 11b thus maintains the temperature of the substrate G at a predetermined level by using an AC voltage output from the AC power source 14.

A cylindrical opening is formed at the bottom surface of the processing container 10, with one end of a bellows 15 attached to the circumferential edge of the opening on the bottom side. The other end of the bellows 15 is fastened to an elevator plate 16. The opening at the bottom surface of the processing container 10 is thus sealed with the bellows 15 and the elevator plate 16.

The susceptor 11, supported at a cylindrical member 17 disposed on the elevator plate 16, moves up and down as one with the elevator plate 16 and the cylindrical member 17, so as to adjust the height of the susceptor 11 at a position optimal for a specific processing operation. In addition, a baffle plate 18 is disposed around the susceptor 11 in order to control the gas flow in the processing chamber U in the optimal state.

A vacuum pump (not shown) disposed outside the processing container 10 is provided near the bottom of the processing container 10. As the gas is discharged with the vacuum pump from the processing container 10 via a gas discharge pipe 19, the pressure inside the processing chamber U is lowered until a desired degree of vacuum is achieved.

At the lid 20, the lid main body 21, six rectangular waveguides 33, a slot antenna 30 and a dielectric member constituted with a plurality of dielectric parts 31 are disposed.

The six rectangular waveguides 33 (correspond to the “waveguide”) have a rectangular cross-section and are disposed parallel to one another inside the lid main body 21. The space inside each waveguide is filled with a dielectric material 34 such as a fluororesin (e.g., Teflon™), alumina (Al2O3) or quartz. Thus, the guide wavelength λg1 within each rectangular waveguide 33 is controlled as indicated in expression; λg1=λc/ε1)^{1/2}. Λc and ε1 in the expression respectively represent the wavelength in free space and the dielectric constant of the dielectric member 34.

Each of the rectangular waveguides 33 has an open at the upper portion through which a movable portion 35 is allowed to move up/down freely. The movable portion 35 may be constituted of a nonmagnetic, electrically conductive material such as aluminum.

Outside the lid main body 21, an elevator mechanism 36 is disposed at the upper surface of each movable portion 35 so as to move the movable portion 35 up/down. This structure allows the movable portion 35 to move to a point level with the upper surface of the dielectric material 34 so as to freely adjust the height of the rectangular waveguide 33.

The slot antenna 30, located on the bottom side of the lid main body 21, is formed as an integrated part of the lid main body 21. The slot antenna 30 may be constituted of a nonmagnetic metal such as aluminum. As shown in FIG. 2, 13 slots (openings 37) of the slot antenna 30 are formed in series at the bottom surface of each rectangular waveguide 33. The space inside each slot 37 is filled with a dielectric member constituted of a fluororesin, alumina (Al2O3) or quartz and the dielectric member enables control of the guide wavelength λ g2 inside each slot 37, as indicated in expression: λg2=λc/ε₂)^{1/2}. Λc and ε₂ in the expression respectively represent the wavelength in free space and the dielectric constant of the dielectric member inside the slot 37.

(Dielectric Member)

The dielectric member is constituted with 39 dielectric parts 31. Each of the dielectric parts 31 is formed in the shape of a tile. 13 dielectric parts 31 are disposed in three rows so that each row of dielectric parts ranges over two rectangular waveguides 33 connected to one microwave generator 40 via a Y branch pipe 41.

Each dielectric part 31 is installed so as to range over two slots with y coordinates equal to each other among the 26 (13 slots×2 rows) slots 37 formed at the bottom surfaces of the two adjacent rectangular waveguides 33 (i.e., the two rectangular waveguides 33 connected to each microwave generator 40 via a Y branch pipe 41). The structure described above includes a total of 39 (13×3 rows) dielectric parts 31 mounted at the bottom surface of the slot antenna 30. It will hereinafter be described the internal structure of dielectric parts 31. It is noted that the function for supplying into the processing chamber U microwaves propagated through the dielectric member (a plurality of dielectric parts 31) and passed through the slots 37 of the slot antenna 30 is achieved by a microwave supply unit (not shown).

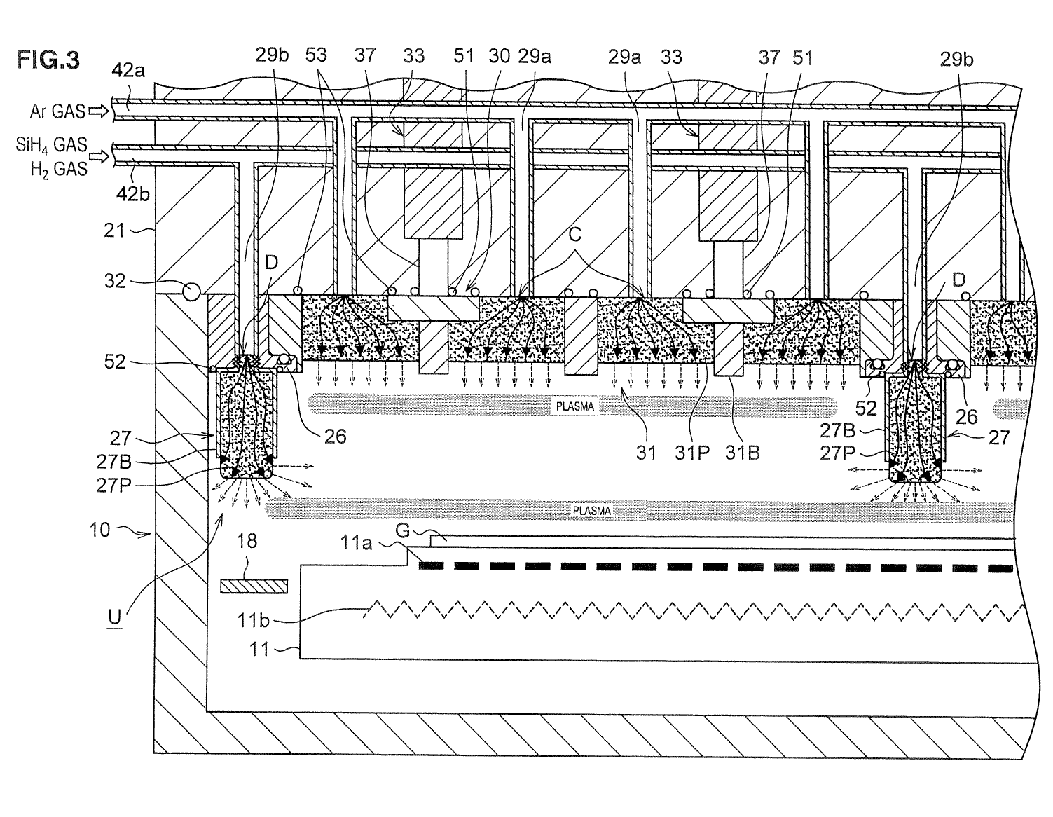

As shown in FIGS. 1 and 3, recessed portions and projecting portions are formed at the surface of each dielectric part 31 facing opposite the substrate G. The presence of at least either recessed portions or projecting portions formed at the surface of the dielectric parts 31 increases the loss of electrical field energy as the surface wave is propagated over the surface of the dielectric part 31 and thus, the extent of surface wave propagation is suppressed. As a result, the occurrence of a standing wave is inhibited, thereby assuring generation of uniform plasma.

It is to be noted that any number of slots 37 may be formed at the bottom surface of each rectangular waveguide 33. Twelve slots 37, for instance, may be formed at the bottom surface of each rectangular waveguide 33 and a total of 36 (12×3 rows) dielectric parts 31 may be disposed at the bottom surface of the slot antenna 30, instead. In addition, the quantity of slots 37 present at the top surface of each dielectric part 31 does not need to be two, and there may be a single slot 37 or three or more slots 37 present at the top surface of each dielectric part 31.

At the bottom surface of the slot antenna 30, a latticed beam 26 is disposed so as to support 39 dielectric parts 31 disposed over the three rows with 13 dielectric parts 31 set in each row, as shown in FIG. 2. The beam 26 is constituted of a nonmagnetic material such as aluminum.

(Gas Nozzles)

As shown in FIG. 3, The gas nozzles forming with threaded at the top thereof may be locked by forming numerous insertion holes with threaded inner surfaces at the bottom surface of the beam 26, inserting the gas nozzles 27 at the insertion holes and interlocking the threaded portions of the insertion holes of the beam 26 and the threaded portions of the top of the nozzles 27. Alternatively, the gas nozzles 27 may be locked onto the beam 26 with an adhesive or they may be mounted at the beam 26 by using a mounting tool.

An O-ring 52 is fitted around the external circumference at the top of each of the gas nozzles 27 over the bottom surface of the beam 26. O-ring 52 isolates the internal spaces in second gas supply pipes 29b where the pressure is sustained at 1 atmosphere from the internal space in the processing chamber U where the pressure is sustained at the vacuum pressure level while assuring the desired level of airtightness in the processing chamber U. As described above, 56 (14×4 rows) gas nozzles 27 may be evenly disposed at the bottom surface of the beam 26, as shown in FIG. 2. It will hereinafter be described the internal structure of gas nozzles 27.

A cooling water pipes 44 in FIG. 1 is connected with a cooling water supply source 45 installed outside the microwave plasma processing apparatus 100 and as cooling water supplied from a cooling water supply source 45 circulates through the cooling water pipes 44 and returns to the cooling water supply source 45, the temperature at the lid main body 21 is maintained at a desired level.

A gas supply source 43 is constituted with a plurality of valves (valves 43a1, 43a3, 43b1, 43b3, 43b5 and 43b7), a plurality of mass flow controllers (mass flow controllers 43a2, 43b2 and 43b6), and argon gas supply source 43a4, a silane gas supply source 43b4 and a hydrogen gas supply source 43b8.

The gases each achieving a desired level of concentration, are supplied into the processing container 10 from the gas supply source 43 by individually controlling the open/closed states of valves (the valves 43a1, 43a3, 43b1, 43b3, 43b5 and 43b7) and the degrees of openness of the mass flow controllers (mass flow controllers 43a2, 43b2 and 43b6). In detail, argon gas is supplied into the processing chamber via a first flow passage 42a and the first gas supply pipes 29a. Silane gas and hydrogen gas are supplied into the processing chamber via a second flow passage 42b and the second gas supply pipes 29b.

According to the structure described above, for instance, 2.45 GHz×3 microwaves are output from the three microwave generators 40 in FIG. 2, transmit the dielectric members 31 through slots 37 via rectangular waveguides 33 and Y branch pipes 41 respectively, and are supplied into the processing chamber U. By raising the gas to plasma with power of the transmitted microwaves, the workpiece (a subject to be processed) is plasma processed.

(Internal Structure of the Dielectric Member)

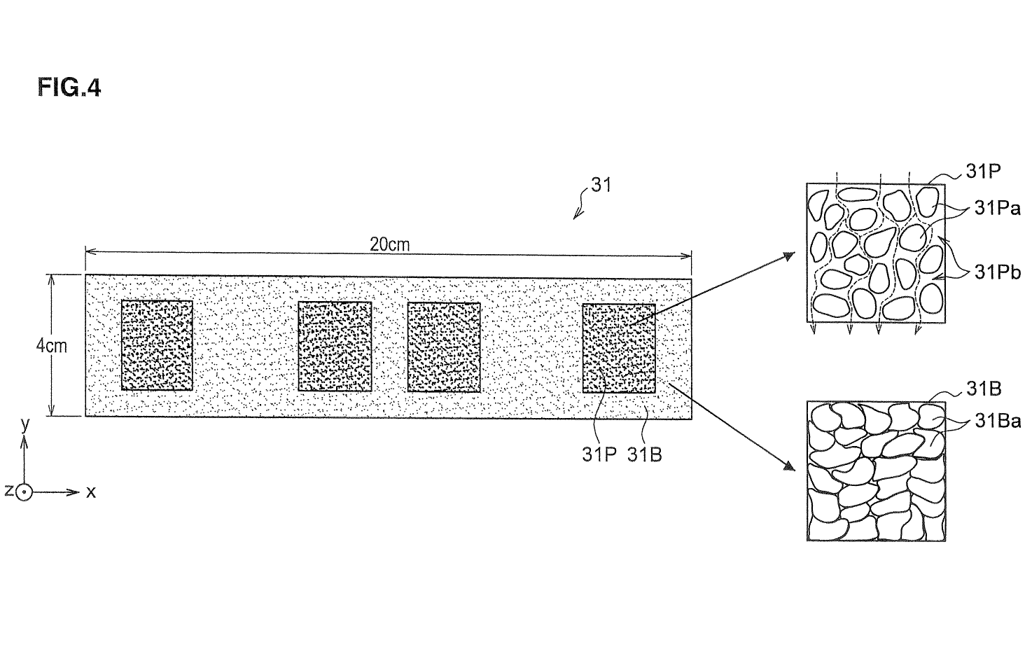

As shown in FIG. 3 presenting an enlarged sectional view and in FIG. 4 presenting a top view, the dielectric parts 31 constituting the dielectric member are each constituted with porous portions (porous member) 31P and dense portions (dense solid portion; dense member) 31B.

(Constituents of the Porous Portions and the Dense Portions)

As shown in an enlargement provided on the upper right side in FIG. 4, the porous portions 31P are formed by mixing crystals 31Pa of a ceramic material such as alumina or silicon carbide, glass 31Pb such as SiO2 and distilled water. Namely, the porous portions 31P assume an internal structure achieved by binding together the ceramic crystals retaining their initial shapes via the glass with pores communicate between the individual ceramic crystals 31Pa. As the gas is made to pass through between the pores, the gas is distributed evenly over the entire porous portions 31P to penetrate the porous portions 31P through their bottoms and is then injected through the bottoms of the porous portions 31P.

It is desirable that the average diameter of the pores in the porous portions 31P be 10˜150 μm and that the porosity in the porous portions be 20˜40%. Such a pore diameter and porosity may be achieved by using alumina powder or silicon carbide powder with an average particle diameter of 30˜150 μm to constitute the ceramic crystals 31Pa.

As shown in an enlargement on the lower right side of FIG. 4, the dense portions 31B are formed by baking or sintering a ceramic material 31Ba selected from alumina, silicon nitride, silicon carbide and zirconia through a heat treatment. Thus, the ceramic crystals in the dense portions 31B do not retain their initial shapes with no gap present between the individual crystals. This means that the gas may not travel through the dense portions 31B.

Preferably, the coefficient of thermal expansion of the glass 31Pb, one of the constituents of the porous portions 31P is smaller than the coefficient of thermal expansion of the ceramic material 31Pa, which is the other constituents of the porous portions 31P and the coefficient of thermal expansion of the ceramic material 31Ba constituting the dense portions 31B, so as to ensure that there is no gap present at the interface between the porous portions 31P and the dense portions 31B after the sintering process by using glass with a low coefficient of thermal expansion and to increase the strength of the porous portions 31P by leaving the glass 31Pb functioning as a binding material in the porous portions 31P in a state in which a compressive stress is applied thereto.

In addition, preferably, the average particle diameter of the glass powder is smaller than the average particle diameter of the ceramic powder, since if the average particle diameter of the glass powder was greater than the average particle diameter of the ceramic powder, the presence of such glass powder would not allow the ceramic powder to be charged readily, which, in turn, would induce baking contraction during the sintering process executed at a temperature equal to or higher than the glass softening point. In consideration of this factor, it is better that the average particle diameter of the glass powder is equal to or less than ½ the average particle diameter of the ceramic powder and it is even more better that the average particle diameter of the glass powder is equal to or less than ⅓ the average particle diameter of the ceramic powder.

While there are no particular restrictions imposed with regard to the quantity of glass powder to be added, it is better to add only a small quantity of glass powder, since the presence of a large quantity of glass powder would not allow the ceramic powder to be charged readily and thus induce baking contraction, in case of glass powder with a large particle diameter. However, if the quantity of glass powder was too small, the bonding strength with which the ceramic powder is bonded would be lowered, to cause some of the ceramic particles to become loose or lost. For this reason, a sufficient quantity of glass powder at which a specific level of bonding strength is assured and the ceramic particles are not allowed to become loose or lost, must be added. More specifically, while the quantity of glass powder should be adjusted by taking into consideration the target porosity, the ceramic particle size, the baking temperature, the glass viscosity and the like, it is preferable that the glass powder is added and mixed in a quantity accounting for approximately 5˜30% of the quantity of the ceramic powder under normal circumstances.

(Positional Arrangement of the Porous Portions and the Dense Portions)

As shown in FIG. 4, at the upper surface of each dielectric part 31, four porous portions 31P assuming a tile-like shape, are disposed so as to be exposed to the outside, with the areas around the porous portions reinforced with dense portions 31B. In addition, as shown in FIG. 3, the two slots 37 disposed at the top surface of the dielectric part 31 are each closed off with dense portions 31B assuming the shape of a flat plate disposed at the bottom of the slot 37. O-rings 51 are mounted at the upper surface of dense portions 31B over the outer circumference of each slot 37 at the bottom end thereof. Thus, the internal spaces in the slots 37 where the pressure is sustained at 1 atmosphere are isolated from the internal space in the processing chamber U where the pressure is sustained at the vacuum pressure level, thereby assuring a high level of airtightness in the processing chamber U.

In addition, dense portions 31B assuming the shape of a flat plate are disposed at the peripheral areas of the dielectric part 31 supported on the beam 26 and at the center of the dielectric part 31 and under the slots 37 so as to partition the dielectric part 31 and project out beyond the bottom surface of the dielectric part 31. With the plurality of porous portions 31P separated from one another via dense portions 31B as described above, the gas may be injected through the bottom surface of each dielectric part 31 with specific directionality.

Furthermore, the presence of the recessed areas and the projecting areas formed at the bottom surface of each dialectic part 31 increases the extent of electrical field energy loss occurring as a surface wave is propagated through the surface of the dialectic part 31 thereby inhibiting propagation of the surface wave. As a result, uniform plasma can be generated by inhibiting occurrence of a standing wave.

An O-ring 53 is mounted (seals) at the circumferential edge of the upper surface of each dense portion 31B disposed adjacent to a porous portion 31P exposed at the top surface of the dielectric part 31, and thus, the internal spaces in the first gas supply pipes 29a, where the pressure is sustained at 1 atmosphere are isolated from the internal space in the processing chamber U, where the pressure is sustained at the vacuum pressure level so as to assure the desired level of airtightness in the processing chamber U.

(Internal Structure Adopted in the Gas Nozzles 27)

As shown in FIG. 3, the gas nozzles 27, too, are constituted with a porous portion 27P and a dense portion 27B as are the dielectric parts 31. More specifically, the piping portion of each gas nozzle 27, communicating with a second gas supply pipe 29b, is constituted with the dense portion 27B with the porous portion 27P filling inside the dense portions. In addition, at the bottom of the gas nozzle 27, the porous portion 27P projects out further than the dense portion 27B so as to be partially exposed into the processing chamber U.

(Method for Manufacturing the Dielectric Part 31 and the Gas Nozzles 27)

The porous portions 31P and the dense portions 31B constituting each dielectric part 31 or the porous portion 27P and the dense portion 27B constituting each gas nozzle 27 are formed together through integrated baking. The method adopted when manufacturing the dielectric parts and the gas nozzles is now explained. It is to be noted that since the gas nozzles 27 can be manufactured through a method identical to the method for manufacturing the dielectric parts 31, the following explanation focuses on the method for manufacturing the dielectric parts 31.

First, water or alcohol is added and mixed into the alumina powder (ceramic powder) and the glass powder, and thus, a slurry to be used to form the porous portions 31P is prepared. Next, the slurry is charged into the dense portions 31B disposed at the specific positions, as explained earlier, thereby forming a dielectric part 31.

After the dielectric part 31 filled with the slurry is dried to a sufficient extent, the porous portions 31P and the dense portions 31B are baked together (the porous portions 31P and the dense portions 31B are formed together by being integrally sintered) at a temperature equal to or higher than the glass softening point. At this time, if the baking temperature was lower than the glass softening point, the porous portions 31P and the dense portions 31B would not be integrated to the required level. If, on the other hands, the baking temperature was too high, the porous portions 31P and the dense portions 31B would become deformed or shrink. For this reason, the baking temperature should be set to the lowest possible level at which the porous portions 31P and the dense portions 31B can still be integrated to a sufficient extent.

In the dielectric part 31 manufactured by baking the porous portions 31P and the dense portions 31B together, as described above, the porous portions 31P and the dense portions 31B are set tightly without creating any gap in between. As a result, the dielectric part 31 assures a high level of tolerance against thermal expansion over a dielectric part in the related art in which the porous portions 31P and the dense portions 31B are manufactured separately and then bonded via an adhesive.

Namely, since the porous portions 31P and the dense portions 31B are bonded via an adhesive constituted of a material different from the constituents of the porous portions 31P and the dense portions 31B in the manufacturing method in the related art, strain occurs over the areas between the porous portions 31P and the adhesive and between the dense portions 31B and the adhesive due to the different coefficients of thermal expansion as the porous portions, the dense portions and the adhesive repeatedly expand and contract during the heat treatment. However, the porous portions 31P and the dense portions 31B baked together are basically constituted of identical materials (their coefficients of thermal expansion are equal to each other) and thus, no strain occurs in these portions in the manufacturing method achieved in the embodiment. Thus, a dielectric part 31 with a high level of tolerance against thermal expansion over the dielectric part in the related art can be manufactured through the manufacturing method in the embodiment.

As a result, the gas having passed through the porous portions (porous portions 27P and 31P) and having become decelerated in the process can be evenly delivered into the processing chamber U while assuring the desired level of airtightness in the processing chamber U with the dense portions (dense portions 27B and 31B) isolating the internal spaces in the gas supply pipes 29 and the slots 37 where the pressure is sustained at 1 atmosphere from the internal space in the processing chamber, where the pressure is sustained at the vacuum pressure level, in the microwave plasma processing apparatus 100 achieved in the embodiment.

In addition, since the porous portions and the dense portions are not manufactured separately but are manufactured together through integrated baking, it is not necessary to perform, for instance, a process of aligning the bonding surfaces of the porous portions and the dense portions, which, in turn, allows the manufacturing costs to be greatly reduced. Moreover, the dielectric parts 31 (and the gas nozzles) achieving a high level of thermal expansion withstanding performance are not readily damaged during plasma processing. As a result, the microwave plasma processing apparatus 100 can be engaged in operation in a stable manner.

(Seal Processing Through Sol-Gel Method)

The dielectric parts 31 and the gas nozzles 27 then undergo seal processing executed by adopting a sol-gel method. It is to be noted that the seal processing executed for the gas nozzles 27 is identical to the seal processing executed for the dielectric parts 31, the following explanation focuses on the seal processing executed for the dielectric parts 31.

More specifically, the porous portions 31P in each dielectric part 31 are soaked in Y2O3 sol-gel with a high level of corrosion resistance so as to coat the porous portions 31P with the Y2O3 sol (in other words, to seal the pores in the dialectic part 31 with the sol (choroid solution) dispersed in an organic solvent), and then, the porous portions are gelled through heat application. The glass (SiO2) in the porous portions 31P having undergone the process does not become corroded by an F gas or a chlorine gas. It is to be noted that a solution selected from the elements in the 3a group in the periodic table, instead of the Y2O3 sol, may be used in this seal processing.

(First Gas Supply Unit and Second Gas Supply Unit)

Next, the method of gas supply adopted in the microwave plasma processing apparatus 100 in the embodiment is explained in reference to FIG. 3.

(Argon Gas Supply)

The ends of the first gas supply pipes 29a are made to open at the four porous portions 31P exposed at the top surface of each dielectric part 31. The first gas supply unit injects an argon gas (equivalent to the first gas) into the processing chamber U through the porous portions 31P formed at the dielectric member (constituted with a plurality of dielectric parts 31). The argon gas having entered the porous portions 31P through the openings C of the first gas supply pipes 29a decelerates as it flows between the individual ceramic crystals and is isotropically dispersed over the entire internal spaces in the porous portions 31P. It is then evenly injected into the processing chamber U through the entire exposed areas of the porous portions 31P near the bottom surfaces thereof, without flowing in a noticeably great quantity along any particular direction.

(Gas Flow Velocity)

The flow velocity Vt of the gas injected into the processing chamber U is determined. Assuming that the pressure P inside the processing container is 1 (Torr) that the total flow rate Q of the gas injected into the processing chamber is 3.33×10⁻⁵ (1/m³) and that the pressure P inside the processing container and the volumetric capacity v of the processing container are constant, the total sectional area A can be calculated as the product of the total area of the dielectric member and the porosity of the dielectric member.

The total area of the dielectric member is calculated as; area of each dielectric part 31×39, and the porosity is 35%. The flow velocity Vt of the gas injected through the porous portions 31P under such circumstances can be calculated as follows by using expression (1).
Vt=Q/A=(3.33×10⁻⁵×760)/(0.243×35%)=0.3 m/s

The calculation results indicate that the flow velocity Vt of the gas injected through the porous portions 31P is approximately 1/1000 (approximately 1/1000 the speed of sound) of the flow velocity with which the gas is injected through numerous injection holes in the related art. The argon gas having decelerated as described above is then evenly injected into the processing chamber through the entire porous portions 31P exposed into the processing chamber U without allowing the argon gas to flow in a significantly greater quantity along any particular direction and thus, a high level of uniformity is achieved with regard to the pressure near the porous portions 31P. As a result, the supplied gas is not excessively agitated and a desirable plasma can be uniformly generated.

(Supply of Silane Gas and Hydrogen Gas)

The second gas supply unit injects a mixed gas containing silane gas and hydrogen gas (equivalent to the second gas) through the porous portions 27P each formed at one of the plurality of gas nozzles 27 from positions lower than the argon gas injection positions.

From the opening ends D of the second gas supply pipes 29b passing through the beam 26, the silane gas and the hydrogen gas enter the porous portions 27P, become decelerated as they flow between the ceramic crystals and are radially dispersed over the entire internal spaces in the porous portions 27P to penetrate the porous portions 27P to the bottoms thereof. Then, the mixed gases are evenly injected into the processing chamber U through the entire exposed areas at the bottoms of the porous portions 27P without flowing in a significantly greater quantity along any particular direction. Thus, the silane gas and the hydrogen gas, having decelerated to approximately 0.3 m/s, are evenly injected at positions lower than the argon gas injection positions.

By injecting the gases through the porous portions 31P at the dielectric parts 31 and through the porous portions 27P in the gas nozzles 27 evenly into the processing chamber at a low speed, as described above, any excessive agitation in the argon gas, the silane gas and the hydrogen gas is inhibited.

Thus, following the plasma ignition of the argon gas, the mixed gas constituted of the silane gas and the hydrogen gas supplied into the processing chamber is dissociated into SiH3 radicals which constitute a precursor for the formation of a good quality film (i.e., the dissociation of the mixed gas does not progress to generation of SiH2 radicals) at the desired position with the electrical field energy, the level of which has been lowered after raising the argon gas to plasma, without becoming too agitated. With the plasma thus generated, a very high-quality amorphous silicon film can be formed on the substrate G.

The microwave plasma processing apparatus 100 achieved in the embodiment was engaged in an actual test operation. The processing conditions selected for the test operation were; the pressure in the processing chamber U set to 400 mTorr (53.2 Pa) and the microwave power set to 1.8 kW×3 (three microwave generators 40 were utilized). It is to be noted that the glass substrate may measure 730 mm×920 mm or more, and the present invention may be adopted in conjunction with glass substrates measuring 730 mm×920 mm in the G4.5 substrate size (the inner diameter of the chamber: 1000 mm×1190 mm) and 1100 mm×1300 mm in the G5 substrate size (the inner diameter of the chamber: 1470 mm×1590 mm), for instance.

An argon gas, a silane gas and a hydrogen gas were used as the gas constituents, with the flow rate for the argon gas set to 1520 sccm, the flow rate for the silane gas set to 140 sccm and the flow rate for the hydrogen gas set to 140 sccm. In addition, the temperature at the susceptor 11 (stage) was sustained at 380° C. so as to keep the temperature of the glass substrate at 308° C. As explained earlier, the argon gas was injected through the dielectric parts 31 disposed at the upper stage, whereas the silane gas and the hydrogen gas were injected through the gas nozzles 27 disposed at the lower stage.

In the test operation, the individual gases, having become decelerated to 125×10⁻³ m/s to 250×10⁻³ m/s, were evenly injected through the entire lower areas of the porous portions 31P in the dielectric parts 31 and through the entire lower surfaces of the porous portions 27P of the gas nozzles 27. Thus, uniform plasma was generated in a stable manner and a high-quality amorphous silicon film was formed at the substrate G without excessive agitation in the argon gas supplied at the upper level and the silane gas and the hydrogen gas supplied at the lower level.

It is to be noted that while the microwave power was set to 2.2 w/cm² in the test operation described above, the present invention is not limited to this example as long as the microwave power is set within a range of 1 w/cm² to 8 w/cm² and it is particularly desirable to set the microwave power within the range of 2.2 w/cm² to 3 w/cm².

While there is a concern that plasma may be generated inside the porous portions constituting part of the dielectric parts 31 and the gas nozzles 27, the mean free path of the argon gas is approximately 80 mm when the pressure is 1 mTorr and the ambient temperature is at room temperature. Accordingly, the mean free path of the argon gas within the processing chamber U at room temperature when the pressure is several tens of mTorr will be approximately several millimeters. The average pore diameter in the porous portions is approximately 10˜150 μm. This means that the argon gas having entered the porous portions will mostly collide with the inner walls of the pores. For this reason, it is assumed that no plasma is generated within the porous portions.

In the embodiment described above, the first gas is supplied through the porous portions 31P at the plurality of dielectric parts 31 and the second gas is supplied through the porous portions 27P at the gas nozzles 27. However, the gas supply method that may be adopted in conjunction with the present invention is not limited to this example and, for instance, the first gas may be supplied through the porous portions 31P at some of the dielectric parts 31 among the plurality of dielectric parts 31 and the second gas may be supplied through the porous portions 31P at the remaining dielectric parts 31.

In addition, the first gas may be supplied through the porous portions 27 at some of the gas nozzles 27 among the plurality of gas nozzles 27 and the second gas may be supplied through the porous portions 27P at the remaining gas nozzles 27.

(Variations)

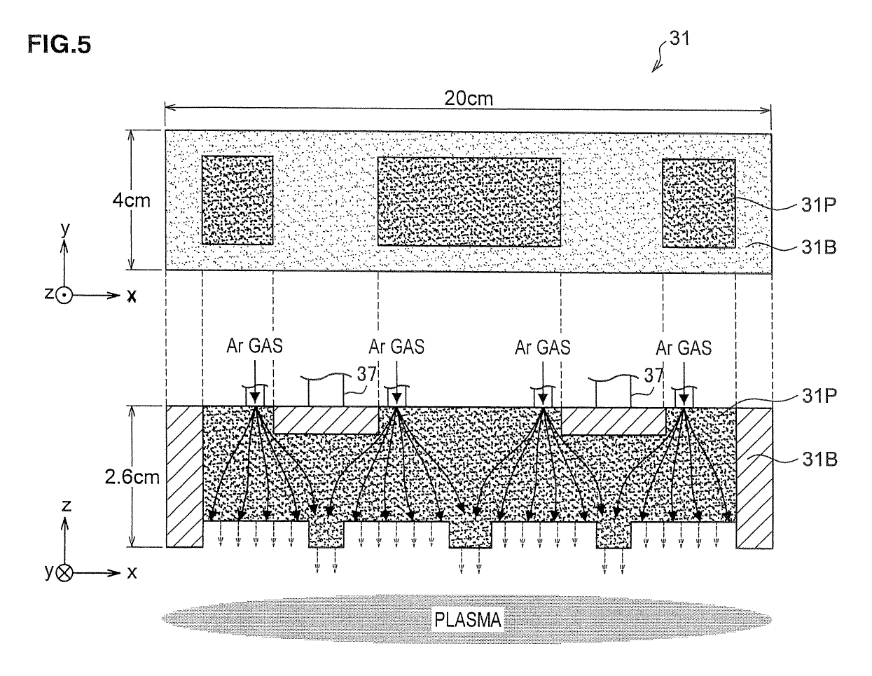

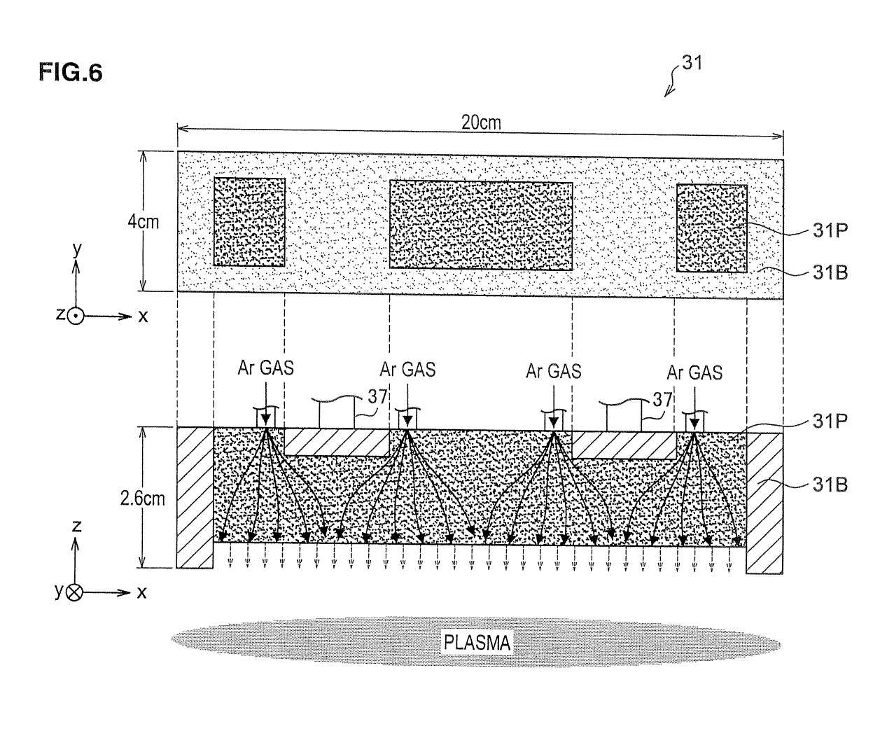

The dense portions 31B and the porous portions 31P constituting the dielectric parts 31 may assume the positional relationship shown in FIG. 5 or FIG. 6, instead of that shown in FIGS. 3 and 4.

In FIGS. 5 and 6, the section of the dense portions 31B disposed under the slots 37 is not T-shaped but assumes the shape of a flat plate so as to close off the slots 37. In addition, dense portions 31B assuming the shape of a flat plate are disposed at the two ends of each dielectric part 31 supported on the beam 26 so as to project out beyond the bottom surface of the dielectric part 31. The porous portions 31P may be formed to include recessed areas and projecting areas at the bottom surface of the dielectric part 31, as shown in FIG. 5, or the dielectric parts 31 may each have a flat bottom surface, as shown in FIG. 6.

In the structure shown in FIG. 5 or FIG. 6, the porous portions 31P ranges continuously without being partitioned by the dense portions 31B inside each dielectric part 31 and, as a result, the gas is allowed to disperse more freely over a wider range to penetrate the entire dielectric part 31 and is then injected more evenly through the entire bottom surface of the dielectric part 31. In addition, by forming projecting areas in the porous portions 31P at the bottom surface of each dialectic part 31 as shown in FIG. 5, propagation of the surface wave can be inhibited via the presence of the recessed areas and the projecting areas at the bottom surface of the dielectric part 31.

Under normal circumstances, it is better that the binding energy of the first gas (e.g., argon gas) injected through the bottom surfaces of the dielectric parts 31 be greater than the binding energy of the second gas (e.g., silane gas) injected through the bottoms of the gas nozzles 27.

The ionization energy of Ar is 15.759 (eV). In addition, the binding energy with which H molecules are bound together is 4.48 (eV) and the binding energy with which Si molecules and H molecules become bound is 3.2 (eV). This means that an amorphous silicon CVD process should be executed by supplying the argon gas with greater energy than the silane gas or the hydrogen gas from the upper side of the processing container 10 to be used as the first gas and supplying the mixed gas containing the silane gas and the hydrogen gas from lower side of the processing container 10 to be used as the second gas, as in the embodiment.

However, under special circumstances, in which the mixed gas containing a plurality of different types of gas constituents includes an excessive reaction, the injection positions for the individual gases should be determined by ensuring that such an excessive reaction does not occur, regardless of the binding energy levels of the first gas and the second gas.

The operations of the individual units, executed in the embodiment as described above, are correlated and thus, they may be regarded as a series of operations by bearing in mind how they relate to one another. By considering them as a sequence of operations, the embodiment of the plasma processing apparatus according to the present invention can be remodeled as an embodiment of a plasma processing method.

While the invention has been particularly shown and described with respect to a preferred embodiment thereof by referring to the attached drawings, the present invention is not limited to these examples and it will be understood by those skilled in the art that various changes in form and detail may be made therein without departing from the spirit, scope and teaching of the invention.

For instance, while an explanation is given above in reference to the embodiment on an example in which the present embodiment is adopted in a plasma processing apparatus engaged in operation to process large glass substrates for large display device production, the present invention may also be adopted in plasma processing apparatuses engaged in semiconductor device production. Namely, in a plasma processing apparatus in which microwaves are supplied through linear slots formed at an RLSA (radial line slot antenna) to plasma process a circular semiconductor wafer, equipped with a dielectric shower plate through which the microwaves are transmitted to be supplied into the processing chamber with a gas supplied into the processing chamber through numerous small holes formed at the shower plate, as disclosed in Japanese Laid Open Patent Publication No. H11-297672, a dielectric disk that includes a porous portion and a dense portion may replace the shower plate so as to supply the gas through the porous portion. In addition, in a plasma processing apparatus equipped with shower plates disposed over two stages, as disclosed in Japanese Laid Open Patent Publication No. 2002-299331, a dielectric disk that includes a porous portion and a dense portion may replace the upper shower plate so as to generate plasma with microwaves in the space between the upper and lower shower plates by supplying a gas for plasma generation into the space through the porous portion.

Furthermore, the plasma processing executed in the plasma processing apparatus according to the present invention does not need to be CVD processing, and the plasma processing apparatus according to the present invention may execute all types of plasma processing including ashing and etching.

The present invention may be adopted in a new and improved plasma processing apparatus capable of executing desirable plasma processing by effectively reducing the gas flow velocity.

What is claimed is:

1. A plasma processing apparatus in which plasma is generated with a predetermined gas excited by a microwave and a subject to be processed is processed by the generated plasma, the plasma processing apparatus comprising:
a processing chamber in which the subject to be processed is processed with plasma;
a gas supply unit that supplies the predetermined gas into the processing chamber; and
a microwave supply unit that supplies the microwave into the processing chamber via slots provided in an antenna and via a dielectric member through which the microwave is transmitted; wherein:
the dielectric member has at least partially a porous member and the predetermined gas is introduced into the processing chamber through the porous member.

2. The plasma processing apparatus according to claim 1, wherein:
the dielectric member is comprised of the porous member and a dense member.

3. The plasma processing apparatus according to claim 2, wherein:
the porous member and the dense member are formed to constitute the dielectric member by being integrally sintered.

4. The plasma processing apparatus according to claim 1, wherein:
the dielectric member is constituted with a plurality of dielectric parts through which the microwave supplied via a single slot or a plurality of slots is transmitted, and each of the plurality of the dielectric parts is comprised of a porous member and a dense member; and
the gas supply unit includes a first gas supply unit that supplies a first gas of the predetermined gas into the processing chamber through the porous member formed at the each of the plurality of the dielectric parts.

5. The plasma processing apparatus according to claim 4, further comprising:
a plurality of gas injection members are comprised of a porous member and a dense member, wherein:
the gas supply unit includes a second gas supply unit that supplies a second gas of the predetermined gas into the processing chamber through the porous member formed at each of the plurality of the gas injection members at a position lower than a position at which the first gas is introduced.

6. The plasma processing apparatus according to claim 5, wherein:
the porous member and the dense member comprising the each of the plurality of the dielectric parts are formed together by being integrally sintered, and
the porous member and the dense member comprising the each of the plurality of the gas injection members are formed together by being integrally sintered.

7. The plasma processing apparatus according to claim 2, wherein:
the dense member of the dielectric member is disposed at a specific position so as to assure sealing of the processing chamber.

8. The plasma processing apparatus according to claim 4, wherein:
at least any one of a recessed portion and a projecting portion is formed at the surface of the each of the plurality of the dielectric parts, which surface faces the subject to be processed.

9. The plasma processing apparatus according to claim 4, wherein:
at least any one of a recessed portion and a projecting portion is formed at the surface of the porous member of the each of the plurality of the dielectric parts, which surface faces the subject to be processed.

10. The plasma processing apparatus according to claim 5, wherein:
the dielectric parts and the gas injection members are each sealed through a sol-gel method.

11. The plasma processing apparatus according to claim 5, wherein:
the gas injection members are fixed onto beam supporting the dielectric parts.

12. The plasma processing apparatus according to claim 5, wherein:
the gas injection members have a dense member disposed on the exterior thereof and the porous member formed within the dense member so as to supply the second gas into the processing chamber through the porous member formed at the each of the plurality of the gas injection members at the position lower than the position at which the first gas is introduced.

13. The plasma processing apparatus according to claim 5, wherein:
at least any one of the first gas and the second gas is a mixed gas containing a plurality of gas constituents and the binding energy of the first gas is greater than the binding energy of the second gas unless the mixed gas induces an excessive reaction.

14. The plasma processing apparatus according to claim 4, wherein:
the plurality of the dielectric parts are supported by a latticed beam; and
the latticed beam is constituted of nonmagnetic material.

15. A plasma processing method for generating plasma with a predetermined gas excited by a microwave and processing a subject to be processed by the generated plasma, the plasma processing method comprising steps of:
supplying the microwave into a processing chamber via a dielectric member through which the microwave is transmitted;
introducing the gas into the processing chamber through a porous member that the dielectric member has at least partially; and
generating plasma with the introduced gas excited by the microwave supplied into the processing chamber.

16. The plasma processing method according to claim 15, wherein:
the dielectric member is comprised of the porous member and a dense member formed together by being integrally sintered; and
introducing the gas into the processing chamber through a porous member while assuring sealing of the processing chamber with the dense member.

17. The plasma processing method according to claim 15, wherein:
transmitting the microwave through a plurality of dielectric parts constituting the dialectic member via a single slot or a plurality of slots; and
introducing a first gas of the predetermined gas into the processing chamber through the porous member that each of the plurality of the dielectric parts has at least partially.

18. The plasma processing method according to claim 15, wherein:
a plurality of gas injection members are comprised of a porous member and a dense member integrally sintered; and
introducing a second gas of the predetermined gas into the processing chamber through the porous member formed at each of the plurality of the gas injection members at a position lower than a position at which the first gas is introduced while assuring sealing of the processing chamber with the dense member.

19. The plasma processing method according to claim 18, wherein:
at least any one of the first gas and the second gas is a mixed gas containing a plurality of gas constituents, and
introducing the first gas of which binding energy is greater than the binding energy of the second gas into the processing chamber through the porous member formed at each of a plurality of dielectric parts constituting the dialectic member and introducing the second gas of which binding energy is lower than the binding energy of the first gas into the processing chamber through the porous member formed at the each of the plurality of the gas injection members unless the mixed gas induces an excessive reaction.
